(19) United States
(12) Patent Application Publication
(10) Pub. No.: US 2021/0088578 A1
(43) Pub. Date: Mar. 25, 2021

(54) SEMICONDUCTOR TEST SOCKET OF HYBRID COAXIAL STRUCTURE AND MANUFACTURING METHOD THEREOF

(71) Applicant: Suzhou Taosheng Electronic Technology Co., Ltd., SUZHOU (CN)

(72) Inventors: Yuanjun SHI, SUZHOU (CN); Lanyong YIN, SHANGHAI (CN); Zongying GAO, SUZHOU (CN); Kai LIU, SUZHOU (CN); Zongmao YANG, FUPING (CN)

(73) Assignee: Suzhou Taosheng Electronic Technology Co., Ltd.

(21) Appl. No.: 16/672,416

(22) Filed: Nov. 1, 2019

(30) Foreign Application Priority Data
Sep. 25, 2019 (CN) 201910914470.1

(51) Int. Cl. G01R 31/28; G01R 1/04

(52) U.S. Cl. CPC G01R 31/2856; G01R 1/0441

(57) ABSTRACT

The present invention relates to a semiconductor test socket of a hybrid coaxial structure and a manufacturing method thereof. The test socket includes a test socket locating plate, an insulation test socket body, a built-in conductive socket body, a built-in conductive socket cover, and an insulation test socket cover. The test socket locating plate, the insulation test socket body, and the insulation test socket cover are sequentially disposed from top to bottom. An opening is provided on the insulation test socket body. The built-in conductive socket body and the built-in conductive socket cover are disposed in the opening. In the present invention, relatively good inter-channel isolation is achieved by using the coaxial structure made of conductive metal, thereby greatly reducing manufacturing costs and a production period of the test socket.

### CROSS-REFERENCE TO RELATED APPLICATIONS

This application claims priority to Chinese Patent Application No. 201910914470.1 with a filing date of Sep. 25, 2019. The content of the aforementioned applications, including any intervening amendments thereto, are incorporated herein by reference.

### TECHNICAL FIELD

The present invention relates to the field of chip test sockets, and in particular, to a semiconductor test socket of a hybrid coaxial structure and a manufacturing method thereof.

### BACKGROUND

In the prior art, a test socket of a coaxial structure is usually used for a semiconductor FPGA chip to test chip performance. As a size of the semiconductor FPGA chip becomes increasingly large and high-frequency communication accounts only for a very small part, the test socket of a coaxial structure is always used for the semiconductor FPGA chip regardless of whether high-frequency communication is performed, thereby causing a continuous increase in chip test costs.

### SUMMARY

The present invention is intended to provide a semiconductor test socket of a hybrid coaxial structure and a manufacturing method thereof, to resolve a prior-art problem that a test socket of a coaxial structure is always used for a semiconductor FPGA chip, thereby causing high chip test costs.

According to an aspect of the present invention, a semiconductor test socket of a hybrid coaxial structure is provided, including a test socket locating plate, an insulation test socket body, a built-in conductive socket body, a built-in conductive socket cover, and an insulation test socket cover, where the test socket locating plate, the insulation test socket body, and the insulation test socket cover are sequentially disposed from top to bottom, an opening is provided on the insulation test socket body, and the built-in conductive socket body and the built-in conductive socket cover are disposed in the opening.

Further, both the insulation test socket body and the insulation test socket cover are installed on the test socket locating plate by using fastening screws.

According to another aspect of the present invention, a manufacturing method of a semiconductor test socket of a hybrid coaxial structure is provided, including the following steps:

(1) processing pinhole cavities on an insulation test socket body and an insulation test socket cover, where the pinhole cavities are kept away from hybrid coaxial space;

(2) processing signal holes and power holes on a built-in conductive socket body and a built-in conductive socket cover;

(3) separately stuffing polymers in the built-in conductive socket body and the built-in conductive socket cover;

(4) baking the built-in conductive socket body and the built-in conductive socket cover that are stuffed with the polymers, so that the polymers are solidified on the built-in conductive socket body and the built-in conductive socket cover;

(5) processing surfaces of the built-in conductive socket body and the built-in conductive socket cover on which the polymers are solidified;

(6) processing signal holes, power holes, and ground holes on the built-in conductive socket body and the built-in conductive socket cover;

(7) assembling a probe of a coaxial structure, the built-in conductive socket body of a coaxial structure, and the built-in conductive socket cover;

(8) inserting the built-in conductive socket body and the built-in conductive socket cover in an opening on the insulation test socket body;

(9) installing the probe on the insulation test socket body and closing the insulation test socket cover; and

(10) installing and fastening the insulation test socket body and the insulation test socket cover on a test socket locating plate by using screws.

Further, step (3) is specifically as follows: in a vacuum environment, stuffing the polymers in the signal holes of the built-in conductive socket body and the built-in conductive socket cover through roll-in.

Further, step (4) is specifically as follows: placing the built-in conductive socket body and the built-in conductive socket cover that are stuffed with the polymers in an oven, baking them at 120° C. for 30 min, baking them at 155° C. for 30 min, and baking them at 190° C. for 60 min.

Beneficial effects of the foregoing technical solutions of the present invention are as follows:

In the present invention, relatively good inter-channel isolation is achieved by using the coaxial structure made of conductive metal, thereby greatly reducing manufacturing costs and a production period of the test socket. In addition, an insertion loss of −1 dB/40 GHz and a return loss of −10 dB/40 GHz can be achieved for high-frequency signals, and the inter-channel isolation exceeds −40 dB/20 GHz.

### BRIEF DESCRIPTION OF DRAWINGS

FIG. 1 is an exploded diagram of a test socket according to the present invention; and

FIG. 2 is a top view of a test socket according to the present invention.

A list of parts represented by all reference signs in the drawings is as follows:
1—test socket locating plate, 2—insulation test socket body, 3—built-in conductive socket body, 4—built-in conductive socket cover, 5—insulation test socket cover, 6—chip

### DESCRIPTION OF EMBODIMENTS

To make the objectives, technical solutions, and advantages of the embodiments of the present invention clearer, the following clearly and completely describes the technical solutions in the embodiments of the present invention with reference to the accompanying drawings in the embodiments of the present invention. Apparently, the described embodiments are some but not all of the embodiments of the present invention.

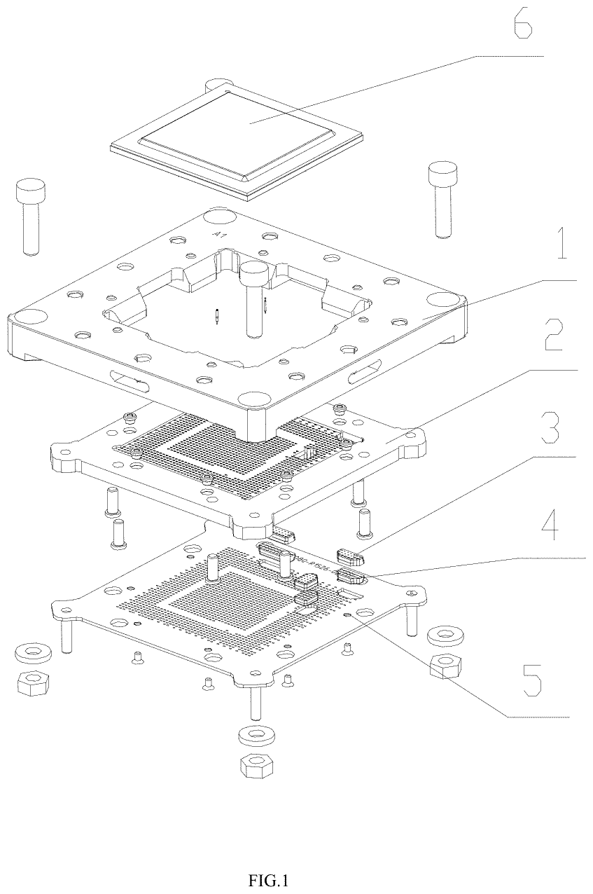

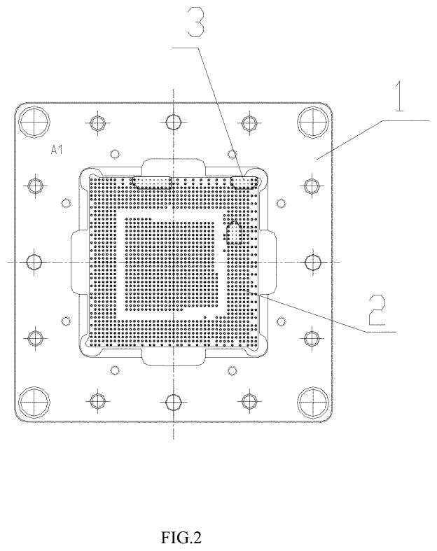

As shown in FIG. 1 and FIG. 2, a semiconductor test socket of a hybrid coaxial structure in this embodiment includes a test socket locating plate 1, an insulation test socket body 2, a built-in conductive socket body 3, a built-in conductive socket cover 4, and an insulation test socket cover 5. A locating slot is provided on the test socket locating plate 1 to place and locate a chip 6. The test socket locating plate 1, the insulation test socket body 2, and the insulation test socket cover 5 are sequentially disposed from top to bottom. Both the insulation test socket body 2 and the insulation test socket cover 5 are installed on the test socket locating plate 1 by using fastening screws. An opening is provided on the insulation test socket body 2. The built-in conductive socket body 3 and the built-in conductive socket cover 4 are disposed in the opening.

A manufacturing method of the semiconductor test socket of a hybrid coaxial structure includes the following steps:

(1) Process pinhole cavities on the insulation test socket body 2 and the insulation test socket cover 5, where the pinhole cavities are kept away from hybrid coaxial space.

(2) Process signal holes and power holes on the built-in conductive socket body 3 and the built-in conductive socket cover 4.

(3) In a vacuum environment, stuff the polymers in the signal holes of the built-in conductive socket body and the built-in conductive socket cover through roll-in.

(4) Place the built-in conductive socket body 3 and the built-in conductive socket cover 4 that are stuffed with the polymers in an oven, bake them at 120° C. for 30 min, bake them at 155° C. for 30 min, and bake them at 190° C. for 60 min, so that the polymers are solidified on the built-in conductive socket body 3 and the built-in conductive socket cover 4.

(5) Process surfaces of the built-in conductive socket body 3 and the built-in conductive socket cover 4 on which the polymers are solidified.

(6) Process signal holes, power holes, and ground holes on the built-in conductive socket body 3 and the built-in conductive socket cover 4.

(7) Assemble a probe of a coaxial structure, the built-in conductive socket body 3 of a coaxial structure, and the built-in conductive socket cover 4.

(8) Insert the built-in conductive socket body 3 and the built-in conductive socket cover 4 in the opening on the insulation test socket body 2.

(9) Install the probe on the insulation test socket body 2 and close the insulation test socket cover 5.

(10) Install and fasten the insulation test socket body 2 and the insulation test socket cover 5 on the test socket locating plate 1 by using screws.

To sum up, in the present invention, relatively good inter-channel isolation is achieved by using the coaxial structure made of conductive metal, thereby greatly reducing manufacturing costs and a production period of the test socket. In addition, an insertion loss of −1 dB/40 GHz and a return loss of −10 dB/40 GHz can be achieved for high-frequency signals, and the inter-channel isolation exceeds −40 dB/20 GHz.

Finally, it should be noted that the foregoing embodiments are merely intended for describing the technical solutions of the present invention, but not for limiting the present invention. Although the present invention is described in detail with reference to the foregoing embodiments, persons of ordinary skill in the art should understand that they may still make modifications to the technical solutions described in the foregoing embodiments or make equivalent replacements to some or all technical features thereof, without departing from the scope of the technical solutions of the embodiments of the present invention.

We claim:

1. A semiconductor test socket of a hybrid coaxial structure, comprising a test socket locating plate, an insulation test socket body, a built-in conductive socket body, a built-in conductive socket cover, and an insulation test socket cover, wherein the test socket locating plate, the insulation test socket body, and the insulation test socket cover are sequentially disposed from top to bottom, an opening is provided on the insulation test socket body, and the built-in conductive socket body and the built-in conductive socket cover are disposed in the opening.

2. The semiconductor test socket of a hybrid coaxial structure according to claim 1, wherein both the insulation test socket body and the insulation test socket cover are installed on the test socket locating plate by using fastening screws.

3. A manufacturing method of a semiconductor test socket of a hybrid coaxial structure, comprising the following steps:
(1) processing pinhole cavities on an insulation test socket body and an insulation test socket cover, wherein the pinhole cavities are kept away from hybrid coaxial space;
(2) processing signal holes and power holes on a built-in conductive socket body and a built-in conductive socket cover;
(3) separately stuffing polymers in the built-in conductive socket body and the built-in conductive socket cover;
(4) baking the built-in conductive socket body and the built-in conductive socket cover that are stuffed with the polymers, so that the polymers are solidified on the built-in conductive socket body and the built-in conductive socket cover;
(5) processing surfaces of the built-in conductive socket body and the built-in conductive socket cover on which the polymers are solidified;
(6) processing signal holes, power holes, and ground holes on the built-in conductive socket body and the built-in conductive socket cover;
(7) assembling a probe of a coaxial structure, the built-in conductive socket body of a coaxial structure, and the built-in conductive socket cover;
(8) inserting the built-in conductive socket body and the built-in conductive socket cover in an opening on the insulation test socket body;
(9) installing the probe on the insulation test socket body and closing the insulation test socket cover; and
(10) installing and fastening the insulation test socket body and the insulation test socket cover on a test socket locating plate by using screws.

4. The manufacturing method of a semiconductor test socket of a hybrid coaxial structure according to claim 3, wherein step (3) is specifically as follows: in a vacuum environment, stuffing the polymers in the signal holes of the built-in conductive socket body and the built-in conductive socket cover through roll-in.

5. The manufacturing method of a semiconductor test socket of a hybrid coaxial structure according to claim 3, wherein step (4) is specifically as follows: placing the built-in conductive socket body and the built-in conductive socket cover that are stuffed with the polymers in an oven, baking them at 120° C. for 30 min, baking them at 155° C. for 30 min, and baking them at 190° C. for 60 min.
